(19) United States
(12) Patent Application Publication
(10) Pub. No.: US 2009/0050056 A1
(43) Pub. Date: Feb. 26, 2009

(54) SUBSTRATE PROCESSING APPARATUS AND SEMICONDUCTOR MANUFACTURING METHOD THEREOF

(76) Inventors: Unryu OGAWA, Toyama (JP); Katsuhiko YAMAMOTO, Toyama (JP); Masanori NAKAYAMA, Toyama (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 12/057,019

(22) Filed: Mar. 27, 2008

(30) Foreign Application Priority Data
Mar. 29, 2007 (JP) 2007-088119
Mar. 14, 2008 (JP) 2008-065596

(51) Int. Cl. H01L 21/30

(52) U.S. Cl. 118/696

(57) ABSTRACT

A substrate processing apparatus and a substrate manufacturing method using the substrate processing apparatus which manufactures, with a high production efficiency, a semiconductor having superior electric characteristics in the nitridation process of a gate insulating film are disclosed. The substrate processing apparatus for the substrate manufacturing method includes a processing chamber which processes the substrate, a processing chamber which generates the plasma, a heating unit which heats the substrate, a gas supply source, and a control unit which executes a first process which converts a nitrogen-containing gas supplied to the processing chamber into the plasma by the processing chamber and heats the substrate by the heating unit, and a second process which stops the plasma generation and heating the substrate further at the temperature of not lower than 450° C. by the heating unit.

### INCORPORATION BY REFERENCE

The present application claims priority from Japanese applications JP2007-088119 filed on Mar. 29, 2007 and JP2008-065596 filed on Mar. 14, 2008, the content of which is hereby incorporated by reference into this application.

### BACKGROUND OF THE INVENTION

This invention relates to a substrate processing apparatus which processes a substrate such as a semiconductor substrate or a glass substrate and a semiconductor manufacturing method for the substrate processing apparatus.

In manufacturing the MOS semiconductor device based on the silicon semiconductor substrate, for example, a gate oxide film including a silicon oxide film is required to be formed on the surface of the silicon semiconductor substrate. Also, in manufacturing the thin film transistor (TFT), a gate oxide film is similarly required to be formed on the surface of the silicon layer arranged on a transparent glass substrate. The memories such as DRAM and the flash memory also require a similar gate oxide film. This gate oxide film contributes to the reliability of the semiconductor device, and the silicon oxide film is required to have a high resistance to the dielectric breakdown and a long-term reliability.

In recent years, the CMOS transistor has been reduced in the required voltage to reduce the power consumption, and for this purpose, sufficiently low symmetric threshold voltages are required of the PMOS and NMOS semiconductor elements. To meet this requirement in the PMOS semiconductor element, the conventional gate electrode configured of a polysilicon layer containing n-type impurities has been replaced by a gate electrode configured of a polysilicon layer containing p-type impurities. The boron (B) atoms constituting the p-type impurities which are now normally used, however, are passed from the gate electrode through the gate oxide film and reach the silicon semiconductor substrate in the various heat treatment processes after forming the gate electrode in the semiconductor manufacturing process, thereby changing the threshold voltage of the PMOS semiconductor element.

This phenomenon becomes more conspicuous in the case where the thickness of the gate oxide film is reduced in keeping with the low power due to the reduced size in the design rule and the reduced power consumption of the semiconductor elements.

In order to suppress the diffusion of the boron (B) atoms constituting the impurities into the silicon substrate semiconductor substrate, nitrogen atoms may be introduced into the gate oxide film. Nitrogen atoms can be introduced into the gate insulating film in the ammonia atmosphere at a high temperature using the thermal nitridation method. Also, a method is available to introduce nitrogen atoms into the gate insulating film by the plasma processing (hereinafter referred to as the nitridation process).

As a device for realizing the nitridation process described above, a modified magnetron typed plasma source (MMT) is known in which the plasma is generated by the electric field and the magnetic field, for example, and the substrate is processed using the plasma. The MMT apparatus includes a heater as a heat source in a susceptor for holding the substrate. The critical temperature to which the substrate is heated by this heater is about 700° C. under the internal pressure of 1 to 200 Pa of the processing chamber.

The device described above is disclosed, for example, in JP-A-2003-282567 and JP-A-11-121198.

### SUMMARY OF THE INVENTION

In the case where the gate oxide film is nitrided at a high substrate temperature, the oxygen replaced by nitrogen is diffused also to the boundary between silicon and the oxide film and combined with the silicon to cause the reoxidization. Upon reoxidization in the boundary between the silicon and the oxide film, the oxide film increases in thickness and so does the electric film pressure, thereby making it difficult to reduce the size of the semiconductor.

Also, the nitridation of the gate oxide film with a low substrate voltage can suppress the reoxidization in the silicon boundary. Nevertheless, an unstable binding composition such as Si—O—N remains in the film, and the electrical characteristics of the semiconductor device are adversely affected. Further, the unstable binding composition deteriorates the reproducibility inconveniently for production management.

An object of this invention is to provide a substrate processing apparatus and a semiconductor manufacturing method with the substrate processing apparatus which manufactures a semiconductor superior in electric characteristics by the nitridation process of the gate insulating film. Another object of the invention is to provide a substrate processing apparatus and a semiconductor manufacturing method with the substrate processing apparatus high in production efficiency.

According to this invention, there is provided a substrate processing apparatus comprising a processing chamber which processes a substrate, a processing chamber which generates the plasma, a heating unit which heats the substrate, a gas source, and a control unit which executes a first process in which the gas containing nitrogen supplied is converted to the plasma by the processing chamber and the substrate is heated by the heating unit and a second process in which the plasma generation is stopped and the substrate is heated to 450° C. or higher.

With the nitridation process of the gate insulating film according to this invention, a semiconductor having superior electrical characteristics can be manufactured. Also, a semiconductor high in production efficiency is provided for the nitridation process of the gate insulating film.

Other objects, features and advantages of the invention will become apparent from the following description of the embodiments of the invention taken in conjunction with the accompanying drawings.

### BRIEF DESCRIPTION OF THE DRAWINGS

FIG. 1 is a longitudinal sectional view showing a processing chamber used in the substrate processing apparatus according to an embodiment of the invention.

FIG. 2 is a diagram showing the film composition before PNA.

FIG. 3 is a diagram showing the comparison of the film composition after PNA.

FIG. 4 is a diagram showing the performance of the lamp heating unit according to the invention.

FIG. 5 is a sectional view showing the device used in a comparative example.

### DETAILED DESCRIPTION OF THE INVENTION

Embodiments of the invention are explained below. A plasma processing chamber according to this invention is a substrate processing chamber (hereinafter referred to as the MMT apparatus) which processes the substrate such as a wafer with the plasma using a modified magnetron typed plasma source capable of generating a high-density plasma by an electric field and a magnetic field. In the MMT apparatus, a substrate is arranged in a processing chamber with a secured hermeticity, a reactant gas is introduced into the processing chamber through a showerhead, and while the processing chamber is maintained at a predetermined pressure, high-frequency power is supplied to a discharge electrode, so that an electric field and a magnetic field are formed to cause the magnetron discharge. The electrons released from the discharge electrode drift while at the same time revolving by cycloidal motion. Thus, the service life is lengthened and the ion generation rate improved, thereby making it possible to generate a high-density plasma. In this way, the substrate can be processed with the plasma by various methods including the diffusion such as oxidization or nitridation of the substrate surface by excitation and decomposition of the reactant gas, the process of forming a thin film on the substrate surface and the process of etching the substrate surface.

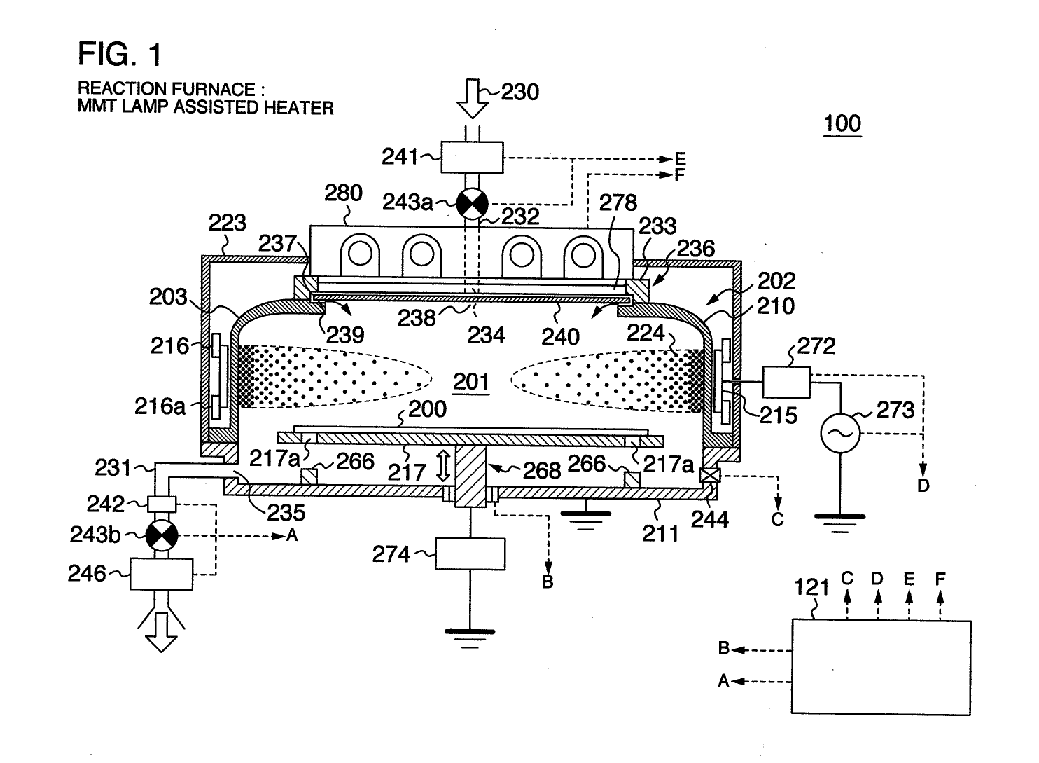

FIG. 1 is a schematic diagram showing the configuration of a MMT apparatus 100 as a substrate processing apparatus. The MMT apparatus 100 includes a processing vessel 203 formed of a dome-type upper vessel 210 constituting a first vessel and a bowl-type lower vessel 211 constituting a second vessel. The upper vessel 210 is covered on the lower vessel 211. The upper vessel 210 is formed of a non-metallic material such as aluminum oxide or quartz, while the lower vessel 211 is formed of, for example, aluminum. An optically transparent window 278 is arranged on the upper surface of the processing vessel 203, and a lamp heating unit (light source) 280 constituting a second heating unit is arranged on the outside of the processing vessel 203 corresponding to the optically transparent window 278. A susceptor 217 constituting a substrate holder (substrate holding unit or substrate mount) integrated with a heater with a first heating unit mounted thereon is configured of aluminum nitride or a non-metallic material such as ceramics or quartz thereby to reduce the metal contamination which otherwise might be introduced into the film during the process.

The lamp heating unit (light source) 280 may be arranged on the surface in opposed relation to the susceptor 217. More than one lamp heating units may be included in such a manner that the wafer 200 mounted on the susceptor 217 is heated from the direction substantially opposite to the heating direction of the first heating unit.

The showerhead 236 is arranged above the processing chamber (reaction chamber) 201, and includes a ring-shaped frame 233, an optically transparent window 278, a gas inlet 234, a buffer room 237, an opening 238, a shield plate 240 and a gas outlet 239. The buffer room 237 is formed as a space which disperses (diffuses) the gas introduced from the gas inlet 234.

The gas inlet 234 is connected with a gas supply pipe 232 which supplies the gas, which in turn is connected to a gas cylinder, not shown, of the reactant gas 230 through a on-off valve 243a and a mass flow controller 241 constituting a flow rate controller (flow rate control unit). The reactant gas 230 is supplied from the showerhead 236 to the processing chamber 201. A gas exhaust port 235 which discharges the gas is formed on the side wall of the lower vessel 211 in such a manner that the gas processed for the substrate flows from around the susceptor 217 toward the bottom of the processing chamber 201. The gas exhaust port 235 is connected with a gas exhaust pipe 231 which discharges the gas, and the gas exhaust pipe 231 is connected to a vacuum pump 246 constituting an exhaust unit through an auto pressure controller (APC) 242 constituting a pressure regulator and an on-off valve 243b.

A cylindrical electrode (ring-shaped electrode unit) 215 constituting a first cylindrical electrode makes up a discharge mechanism (discharge electrode) which excites the reactant gas 230 supplied thereto. The cylindrical electrode 215 surrounds a plasma generating area 224 in the processing chamber 201 arranged on the outer periphery of the processing vessel 203 (upper vessel 210). The cylindrical electrode 215 is connected with a high-frequency power supply 273 which applies high-frequency power through an impedance matching unit 272.

The cylindrical electrode 215, the impedance matching unit 272 and the high-frequency power supply 273 are collectively referred to as a processing chamber.

Also, cylindrical magnets 216, 216a constituting, for example, a cylindrically formed magnetic field-forming mechanism (magnetic field-forming unit) are permanent magnets. The cylindrical magnets 216, 216a are arranged in the neighborhood of the upper and lower ends, respectively, of the outer surface of the cylindrical electrode 215. The upper and lower cylindrical magnets 216, 216a have magnetic poles at the two ends (inner and outer peripheral ends) along the radius of the processing chamber 201, which magnetic poles are directed oppositely to each other. Therefore, the magnetic poles on the inner peripheral portion are different in polarity, so that magnetic lines of force are formed in the direction of the cylindrical axis along the inner peripheral surface of the cylindrical electrode 215.

A susceptor 217 constituting a substrate holder (substrate holding unit) which holds the wafer 200 constituting the substrate is arranged at the center near the bottom of the processing chamber 201. The susceptor 217 is formed of aluminum nitride or a non-metallic material such as ceramics or quartz, and has integrally buried therein a heater (not shown) as a heating mechanism (heating unit) to heat the wafer 200. The heater supplied with power can heat the wafer 200 up to about 500° C.

Also, a second electrode constituting an electrode which changes the impedance is arranged in the susceptor 217. The second electrode is grounded through an impedance changing mechanism 274. The impedance changing mechanism 274 is configured of a coil and a variable capacitor, and by controlling the pattern number of the coil or the capacitance of the variable capacitor, can control the electric potential of the wafer 200 through the electrode and the susceptor 217.

A processing chamber 202 which processes the wafer 200 by the magnetron discharge using a magnetron-type plasma source is configured of at least the processing chamber 201, the processing vessel 203, the susceptor 217, the cylindrical electrode 215, the cylindrical magnets 216, 216a, the showerhead 236 and the exhaust port 235. The wafer 200 can be processed by plasma in the processing chamber 201.

A shield plate 223 which effectively shields the electric and magnetic fields is arranged around the cylindrical electrode 215 and the cylindrical magnets 216, 216a so that the external environment and the devices such as the other processing chambers may not be adversely affected by the electric or magnetic field formed by the cylindrical electrode 215 and the cylindrical magnets 216, 216a.

The susceptor 217 has a susceptor lift mechanism (lift unit) 268 insulated from the lower vessel 211 to move up and down the susceptor 217. The susceptor 217 is also formed with through holes 217a, and at least three wafer pushup pins 266 to push up the wafer 200 are arranged on the bottom surface of the lower vessel 211. The through holes 217a and the wafer pushup pins 266 are arranged in such relative positions that in the case where the susceptor 217 is moved down by the susceptor lift mechanism 268, the wafer pushup pins 266 are passed through the holes 217a without contacting the susceptor 217.

Also, a gate valve 244 constituting a bulkhead is arranged on the side wall of the lower vessel 211. As long as the gate valve 244 is open, the wafer 200 can be transported into or out of the processing chamber 201 by a transport mechanism (transport unit), not shown, while the processing chamber 201 can be closed hermetically in the case where the gate valve 244 is closed.

The controller 121 making up the control unit is configured to control the APC 242, the valve 243b and the vacuum pump 246 through a signal line A, the susceptor lift mechanism 268 through a signal line B, the gate valve 244 through a signal line C, the impedance matching unit 272 and the high-frequency power supply 273 through a signal line D, the mass flow controller 241 and the valve 243a through a signal line E, the impedance changing mechanism 274 and the heater buried in the susceptor through a signal line not shown, and the lamp heating unit 280 through a signal line F.

Now, as one step of the semiconductor device manufacturing process using the processing chamber having the aforementioned configuration, an explanation is given about a method of executing a predetermined plasma processing on the surface of the wafer 200 or the surface of the base film formed on the wafer 200. In the description that follows, the operation of each part making up the MMT apparatus 100 is controlled by the control unit 121.

The plasma processing according to this embodiment includes a first process and a second process. First, the plasma nitridation process making up the first process is explained. The first process is to nitride the gate insulating film.

The wafer 200 is transported into the processing chamber 201 making up the processing chamber 202 from outside of the processing chamber 201 and then further onto the susceptor 217 by the transport mechanism, not shown. This transport operation is described in detail below. The susceptor 217 moves down to a reference transport position, and the forward ends of the wafer pushup pins 266 are passed through the holes 217a formed through the susceptor 217. In the process, the pushup pins 266 are projected by a predetermined height from the surface of the susceptor 217. Next, the gate valve 244 on the lower vessel 211 is opened, and the wafer 200 is placed on the forward ends of the pushup pins 266 by the transport mechanism not shown. Once the transport mechanism is retreated out of the processing chamber 201, the gate valve 244 is closed. With the upward movement of the susceptor 217 by the susceptor lift mechanism 268, the wafer 200 can be mounted on the upper surface of the susceptor 217, and moved up further to a position where the wafer 200 is processed.

The heater buried in the susceptor 217 is preheated, and the wafer 200 transported in is heated to a predetermined wafer processing temperature within the range of 150 to 500° C. This is by reason of the fact that the gate oxide film is not reoxidized at temperatures not higher than 500° C. Incidentally, the pressure of the processing chamber 201 is maintained at a predetermined level within the range of 1 to 200 Pa using the vacuum pump 246 and the APC 242.

Once the wafer 200 reaches and is settled at the processing temperature, a nitrogen-containing gas is introduced toward the upper surface (processing surface) of the wafer 200 arranged in the processing chamber 201 through a gas injection hole 239 of the shield plate 240 from the gas inlet 234. In the process, the gas is assumed to flow at the desired flow rate (say, 100 to 500 sccm). At the same time, the high-frequency power is applied from the high-frequency power supply 273 to the cylindrical electrode 215 through the impedance matching unit 272. The power thus applied has a predetermined output value in the range of 150 to 200 W. In the process, the impedance changing mechanism 274 is controlled at the desired impedance value in advance.

Under the effect of the magnetic field of the cylindrical magnets 216, 216a, the magnetron discharge occurs, and the charge is trapped in the space above the wafer 200, so that a high-density plasma is generated in the plasma generating area 224. By the high-density plasma thus generated, the plasma nitridation process is executed on the surface of the wafer 200 on the susceptor 217.

Upon completion of the plasma nitridation process constituting the first process, the PNA (post nitride anneal) process constituting the second process is started. The PNA process is defined as the process of heating the intended substrate after the plasma nitridation process. The PNA process constituting the second process is explained below.

Upon completion of the plasma nitridation process, power stops being supplied to the cylindrical electrode 215, and the magnetron discharge stops. After the magnetron discharge stops, the lamp heating unit 280 is activated, and the wafer temperature is increased to 450° C. or higher. In the process, the heater buried in the susceptor 217 is kept on from the first process. According to this embodiment, the wafer is heated from two directions (for example, the surface and opposing surface of the substrate). This is by reason of the fact that the binding degree of the Si—O—N binding is generally considered to increase at 450° C. or higher. As long as the substrate temperature is low (about 450° C.), however, a long-time processing is required to improve the binding degree. The higher the substrate temperature, the shorter the binding time. The substrate temperature, therefore, is desirably 530° C. or higher. Nevertheless, it takes a long time to increase the heater temperature. Thus, the best choice is about 530° C. By heating the wafer to this temperature, the unstable Si—N—O binding is eliminated.

Following the first process, the pressure of the processing chamber 201 is maintained at a predetermined level within the range of 1 to 200 Pa using the vacuum pump 246 and the APC 242. The pressure is not required to be regulated from the first process. Further, the gas flow rate is set to the same value as predetermined in the first process. Also, the application of the high-frequency power to the cylindrical electrode 215 is stopped. In the second process, no plasma is generated, and therefore, the application of the high-frequency power to the cylindrical electrode is not required.

Incidentally, at the time of transfer from the first to the second process, the position of the susceptor 217 can be moved in the same processing chamber using the susceptor lift mechanism 268 if required. Although the heater buried in the susceptor 217 and the lamp heating unit 280 are used to heat the substrate to the temperature of not lower than 450° C. according to this embodiment, a single heating unit may be used in another embodiment, or in still another embodiment, three or more heating units may be included.

The processing operation of the first and second processes according to this embodiment are summarized in the table below.

TABLE 1

| | First process: | Second process: PNA |
|---|---|---|
| | plasma nitridation | (post nitride anneal) |
| | process | process |
| Gas flow rate | 100~500 sccm | 100 to 500 sccm |
| | | (maintained at same |
| | | rate as in first |
| | | process) |
| Applied power | 150~200 W | Stop |
| Substrate | 150~500° C. | 530° C. or higher |
| temperature | | |
| Susceptor heater | ON | ON |
| (first heating | | |
| unit) | | |
| Lamp heater | OFF | ON (after stopping |
| (second heating | | magnetron discharge, |
| unit) | | turn on lamp heater) |
| Pressure | 1~200 Pa | 1 to 200 Pa |
| | | (maintained at same |
| | | level as in first |
| | | process) |
| Processing time | Ten seconds to | One minute or two |
| | two minutes | minutes after reaching |
| | | 530° C. (about 5 sec |
| | | to 2 min required |
| | | before 530° C.) |

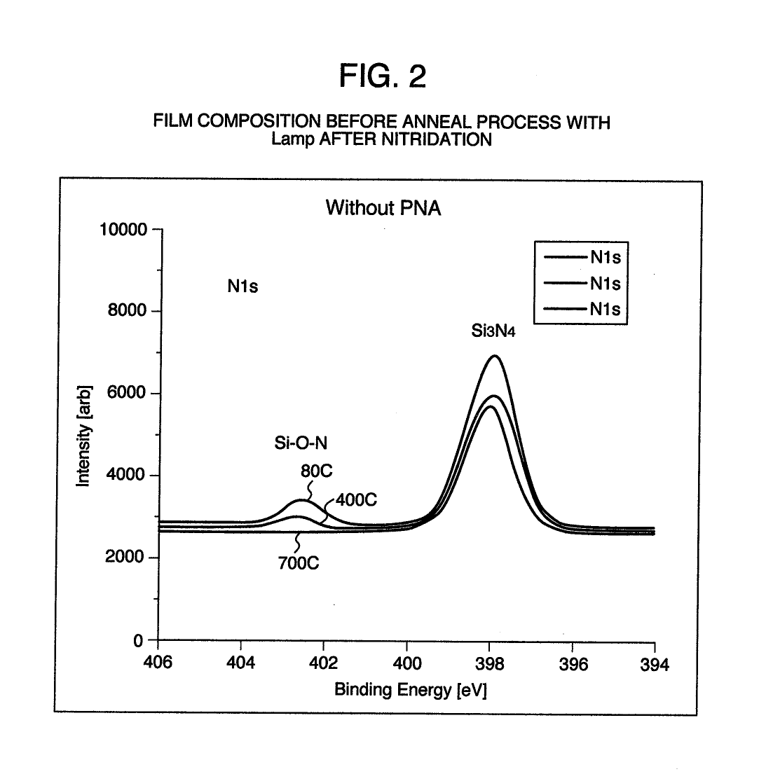

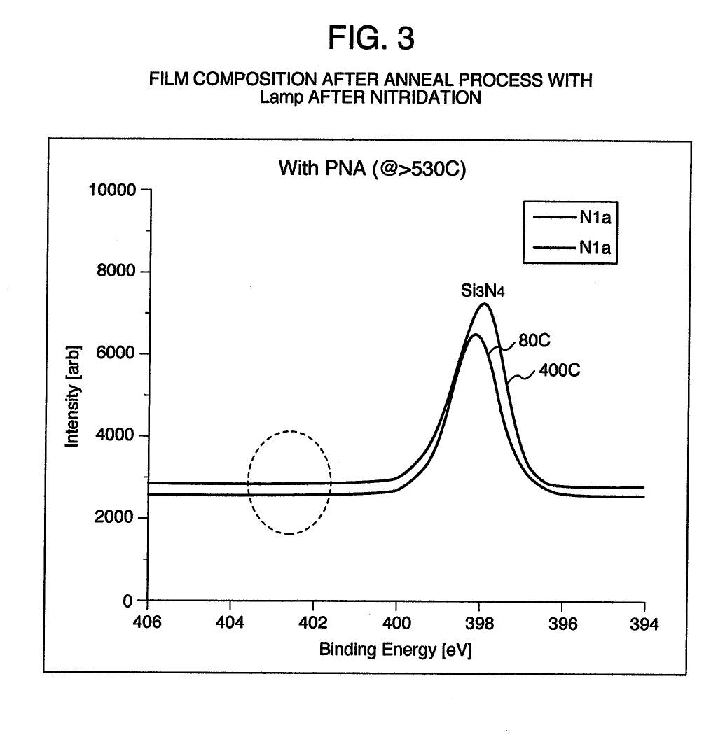

With reference to FIGS. 2 and 3, the effect of PNA is explained. FIGS. 2 and 3 show the film composition. Specifically, FIG. 2 shows the nitridation binding degree (SN1) before PNA, and FIG. 3 the nitridation binding degree (SN1) after conducting PNA at the substrate temperature higher than 530° C. The ordinate represents the signal intensity, and the abscissa the binding energy. Also, reference characters 80C, 400C and 700C designate the substrate temperatures of 80° C., 400C and 700° C., respectively, at the time of the nitridation process.

Consider the binding degree in the range of 404 to 402 eV. It is understood from FIG. 2 that the strength of the substrate at temperatures of 80° C. and 400° C. other than 700° C. is unstable before PNA. FIG. 3 shows, however, that the Si—O—N strength of the substrate is stable at 80° C. and 400° C. after PNA.

As a result, it is understood that the substrate should be heated at a temperature higher than 530° C. in the PNA process. In the case where the substrate temperature is 700° C., the reoxidization occurs in the boundary between silicon and oxide film as described above, and the oxide film is thickened. The nitridation temperature of the substrate, therefore, is desirably not higher than 500° C.

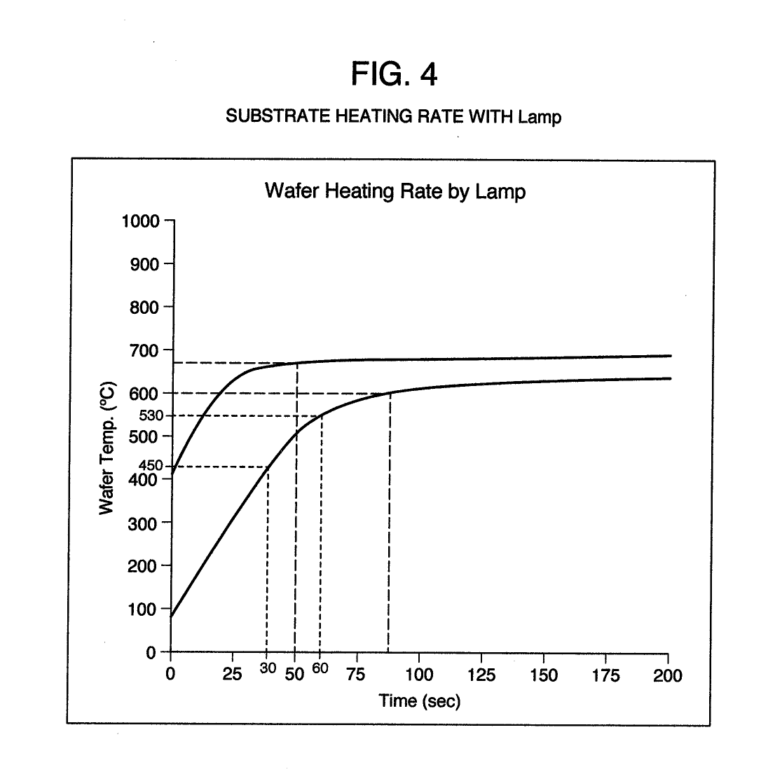

The duration of the activation of the lamp heating unit 280, depending on the temperature of the wafer 200 at the time of activating the lamp heating unit 280, is required to be at least 5 seconds. In the case where the initial temperature (at the time of plasma nitridation processing) of the wafer 200 is 100° C., as shown in FIG. 4 for example, it takes about 60 seconds before reaching 530° C., and therefore, the duration of the activation of at least 60 seconds is required. In the case where the initial temperature (at the time of plasma nitridation processing) is 400° C., on the other hand, it takes about 11 seconds before 530° C. is reached. The initial temperature (at the time of plasma nitridation processing), therefore, is desirably about 400° C. The duration of the activation of at least about 1 minute and 11 seconds is required.

By activating the lamp heating unit 280 as described above, the substrate 200 can be increased to the desired temperature, i.e. 530° C. or higher in a short time.

For subsequent three seconds, the heating operation is performed by maintaining the temperature at 530° C. or higher.

As described above, the higher the initial temperature of the wafer 200, the earlier the target temperature is reached. Taking the throughput into consideration, therefore, the temperature of the substrate 200 after the plasma processing is desirably maintained at about 500° C.

Without using the lamp heating unit 280, the substrate temperature may be increased by use of the heater built in the susceptor 217. As compared with the lamp heating unit 280, however, a long time is required to increase the substrate temperature.

Taking the throughput into consideration, therefore, the substrate 200 is desirably heated in a short time by activating the lamp heating unit 280.

Upon complete plasma processing, the power supply to the cylindrical electrode is stopped and the nitrogen-containing gas discharged from the processing chamber 201. After gas discharge, the wafer 400 is transported out of the processing chamber 201 in the reverse order of the steps for the transportation into the processing chamber 201 using the transport mechanism not shown.

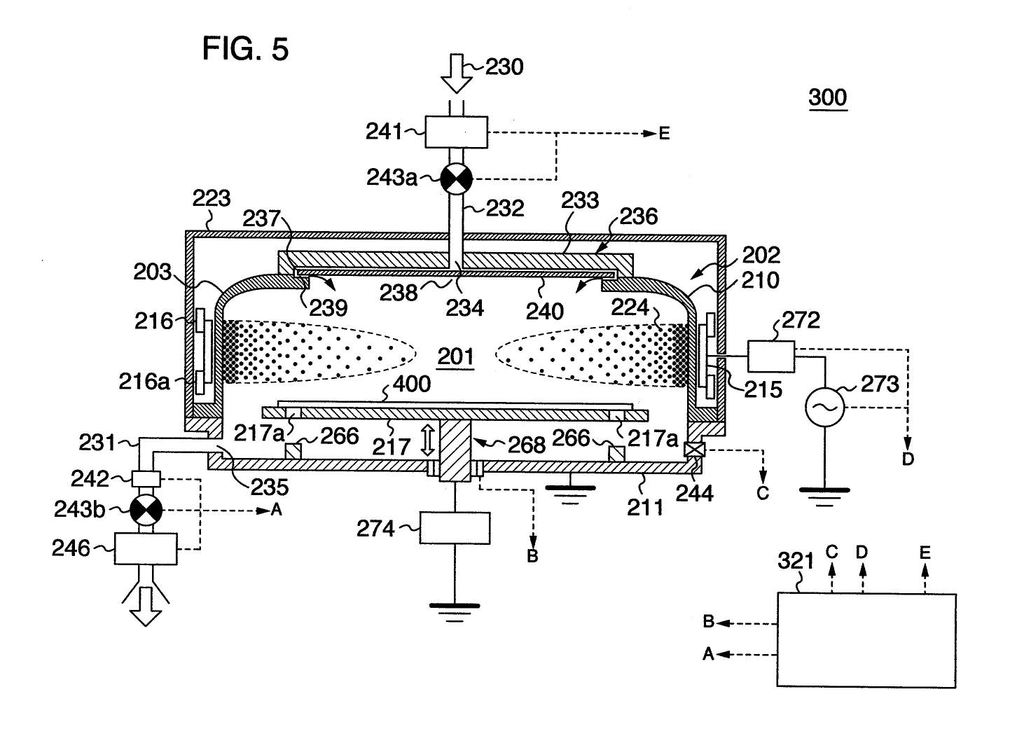

Next, a comparative example is explained with reference to the apparatus having the configuration shown in FIG. 5. In FIG. 5, the same reference numerals as those in FIG. 1 are assumed to have the same functions, respectively, as the latter.

An explanation is given about a method of executing a predetermined plasma processing on the surface of the wafer 400 or the surface of the base film formed on the wafer 400 as one process which manufactures the semiconductor device using the processing chamber having the configuration shown in FIG. 5. In the description that follows, the operation of each part making up the MMT apparatus 300 is controlled by the control unit 321.

The wafer 400 is delivered into the processing chamber 201 and further onto the susceptor 217 by the transport mechanism, not shown, from outside the processing chamber 201 making up the processing chamber 202. Specifically, the susceptor 217 is moved down to a reference transport position, and the forward ends of the wafer pushup pins 266 are passed through the holes 217a formed through the suscepter 217. In the process, the pushup pins 266 are projected to a predetermined height above the surface of the susceptor 217. Next, the gate valve 244 arranged on the lower vessel 211 is opened, and by the transport mechanism not shown, the wafer 400 is placed on the forward ends of the wafer pushup pins 266. Once the transport mechanism is retreated out of the processing chamber 201, the gate valve 244 is closed. With the upward movement of the susceptor 217 by the susceptor lift mechanism 268, the wafer 400 can be mounted on the upper surface of the susceptor 217, and further moved up to the position where it is processed.

The heater buried in the susceptor 217 is preheated, so that the wafer 400 delivered in is heated to a predetermined wafer processing temperature within the range of 150 to 500° C. The temperature of not higher than 500° C. prevents the reoxidization of the gate oxide film.

The pressure of the processing chamber 201 is maintained at a predetermined level within the range of 1 to 200 Pa using the vacuum pump 246 and the APC 242.

Once the wafer 400 reaches the processing temperature and is settled, a nitrogen-containing gas is introduced toward the upper surface (processing surface) of the wafer 200 arranged in the processing chamber 201, through the gas injection hole 239 of the shield plate 240 from the gas inlet 234. In the process, the flow rate is set at a predetermined value (say, 100 to 500 sccm). At the same time, the high-frequency power is applied to the cylindrical electrode 215 from the high-frequency power supply 273 through the impedance matching unit 272. The applied power produces a predetermined output value within the range of 150 to 200 W. The impedance changing mechanism 274 is controlled at the desired impedance value in advance.

Under the effect of the magnetic field from the cylindrical magnets 216, 216a, the magnetron discharge occurs. Then, the charge is trapped in the space above the wafer 400, and a high-density plasma is generated in the plasma generating area 224. With the high-density plasma thus generated, the plasma processing (nitridation process) is executed on the surface of the wafer 400 on the susceptor 217.

Upon complete plasma processing, the power is stopped being supplied to the cylindrical electrode, and the nitrogen-containing gas is discharged from the processing chamber 201. After discharge, the wafer 400 is transported out of the processing chamber 201 in the reverse order to the inward delivery of the substrate, using the transport mechanism not shown.

The substrate 400 transported out of the processing chamber 201 is delivered into the heating unit arranged at a different position. The heating unit may be another MMT apparatus 300 than the MMT apparatus used for the plasma processing or a dedicated one.

The substrate 400 thus transported is heated to a predetermined temperature by the heating unit.

After that, the substrate is transported out of the heating unit by the transport mechanism in the reverse order of the process in which it is delivered in.

Next, this invention is compared with a comparative example.

According to this invention, the substrate is heated in the same processing chamber following the plasma processing. Specifically, if different chambers are used for the processing, the substrate would be transported to the processing chamber for the second process through a substrate transport chamber after a first process, and therefore, the throughput would be reduced by an amount equivalent to the passage through the substrate transport chamber. According to the invention, in contrast, the transport to a different heating unit is not required, and therefore, the throughput is very high as compared with the comparative example.

Also, in the comparative example, the atmosphere is created by a dry pump, and therefore, the vacuum degree is low as compared with the processing chamber where the atmosphere is introduced by use of a vacuum pump. As a result, the substrate is more liable to be oxidized or fouled by the impurities which may attach, during the transportation from the processing chamber which executes the first process to the processing chamber which executes the second process, thereby deteriorating the electric characteristics of the completed semiconductor. According to this invention, in contrast, both the first and second processes are executed in the same chamber (processing chamber), and therefore, reoxidization is not caused and the substrate is not fouled.

Also, in view of the fact that the heating process can be executed in the same device following the plasma processing, a new heating unit other than the plasma processing unit is not required. As a result, the apparatus cost is reduced on the one hand, and the installation in a clean room reduces the required area on the other hand.

Although this invention is explained above with reference to a case using the MMT apparatus, the invention is not limited to the MMT apparatus, but may be embodied using another single wafer processing apparatus. The single wafer processing apparatus is, for example, the parallel plate capacitor type, ICP (inductively coupled plasma) type or ECR (electron cyclotron resonance) type.

The embodiments of the invention explained above are summarized below.

According to a first aspect of the invention, there is provided a substrate processing apparatus comprising a processing chamber which processes a substrate, a processing chamber which generates a plasma, a heating unit which heats the substrate, a gas supply unit and a control unit which executes a first process which converts a nitrogen-containing gas supplied to the processing chamber into a plasma by the processing chamber and heats the substrate by the heating unit, and a second process which stops the plasma generation and heats the substrate to not lower than 450° C.

According to a second aspect of the invention, there is provided a substrate processing apparatus comprising a processing chamber which processes a substrate, a processing chamber which generates a plasma, first and second heating units which heats the substrate, a gas supply unit, and a control unit which executes a first process which converts a nitrogen-containing gas supplied to the processing chamber into a plasma by the processing chamber and heats the substrate by the first heating unit, and a second process which stops the plasma generation and heats the substrate by the first and second heats units.

According to a third aspect of the invention, there is provided the substrate processing apparatus described in the second aspect of the invention, wherein the substrate is heated to not lower than 450° C. in the second process.

According to a fourth aspect of the invention, there is provided a substrate processing apparatus comprising a processing chamber which processes a substrate, a processing chamber which generates a plasma, a substrate mount which mounts the substrate thereon and has a first heating unit which heats the substrate, a second heating unit arranged on a surface facing the substrate mount which heats the substrate surface to be processed, and a control unit which executes a first process which converts a nitrogen-containing gas supplied to the processing chamber into a plasma by the processing chamber and heats the substrate by the first heating unit, and a second process which stops the plasma generation and heats the substrate by the first and second heating units.

According to a fifth aspect of the invention, there is provided the substrate processing apparatus described in any one of the first to fourth aspects of the invention, wherein the substrate temperature in the second process is set at 530° C.

According to a sixth aspect of the invention, there is provided the substrate processing apparatus described in any one of the first to fifth aspects of the invention, wherein the substrate is processed at the temperature of 400° C. in the first process.

According to a seventh aspect of the invention, there is provided a semiconductor manufacturing method using a substrate processing apparatus including a processing chamber which processes a substrate, a processing chamber which generates a plasma, a heating unit which heats the substrate and a gas supply unit, the method comprising a first process which converts a nitrogen-containing gas supplied to the processing chamber into a plasma by the processing chamber and heats the substrate by the heating unit, and a second process which stops the plasma generation and heats the substrate to not lower than 450° C.

According to an eighth aspect of the invention, there is provided a semiconductor manufacturing method using a substrate processing apparatus including a processing chamber which processes a substrate, a processing chamber which generates a plasma, first and second heating units which heat the substrate and a gas supply unit, the method comprising a first process which converts a nitrogen-containing gas supplied to the processing chamber into a plasma by the processing chamber and heating the substrate by the first heating unit, and a second process which stops the plasma generation and heats the substrate by the first and second heating units.

According to a ninth aspect of the invention, there is provided the semiconductor manufacturing method described in the eighth aspect of the invention, wherein the substrate is heated at the temperature of not lower than 450° C. in the second process.

According to a tenth aspect of the invention, there is provided a semiconductor manufacturing method using a substrate processing apparatus including a processing chamber which processes a substrate, a processing chamber which generates a plasma, a substrate mount which mounts the substrate thereof and has a first heating unit which heats the substrate, and a second heating unit arranged on a surface facing the substrate mount which heats the surface of the substrate to be processed, the apparatus further including a control unit which executes a first process which converts a nitrogen-containing gas supplied to the processing chamber into a plasma by the processing chamber and heating the substrate by the first heating unit, and a second process which stops the plasma generation and heats the substrate by the first and second heating units.

According to an 11th aspect of the invention, there is provided the semiconductor manufacturing method described in any one of the seventh to tenth aspects of the invention, wherein the substrate is heated to the temperature of 530° C. in the second process.

According to a 12th aspect of the invention, there is provided a semiconductor manufacturing method described in any one of the seventh to 11th aspects of the invention, wherein the substrate is processed at the temperature of 400° C. in the first process executed in the substrate processing apparatus.

It should be further understood by those skilled in the art that although the foregoing description has been made on embodiments of the invention, the invention is not limited thereto and various changes and modifications may be made without departing from the spirit of the invention and the scope of the appended claims.

1. A substrate processing apparatus comprising:
a processing chamber which processes a substrate;
a processing chamber which generates a plasma;
a heating unit which heats the substrate;
a gas supply source; and
a control unit which executes a first process which converts a nitrogen-containing gas supplied to the processing chamber into a plasma by the processing chamber and heating the substrate by the heating unit, and a second process which stops the plasma generation and heats the substrate further at not lower than 450° C.

2. A substrate processing apparatus comprising:
a processing chamber which processes a substrate;
a processing chamber which generates a plasma;
first and second heating units which heats the substrate;
a gas supply source; and
a control unit which executes a first process which converts a nitrogen-containing gas supplied to the processing chamber into the plasma by the processing chamber into a plasma and heats the substrate by the first heating unit, and a second process which stops the plasma generation and heating the substrate further by the first and second heating units.

3. The substrate processing apparatus according to claim 2,
wherein the substrate is heated at the temperature of not lower than 450° C. in the second process.
